(19) United States
(12) Patent Application Publication
(10) Pub. No.: US 2021/0249553 A1
(43) Pub. Date: Aug. 12, 2021

(54) MASS TRANSFER METHOD AND SYSTEM FOR SEMICONDUCTOR ELEMENT

(71) Applicant: CHONGQING KONKA PHOTOELECTRIC TECHNOLOGY RESEARCH INSTITUTE CO., LTD., Chongqing (CN)

(72) Inventors: Peng Yue ZHANG, Chongqing (CN); Chia-Hua HUANG, Chongqing (CN); Po Fu CHEN, Chongqing (CN); Tzu Ping LIN, Chongqing (CN)

(21) Appl. No.: 17/241,783

(22) Filed: Apr. 27, 2021

Related U.S. Application Data
(63) Continuation of application No. PCT/CN2019/122816, filed on Dec. 3, 2019.

(51) Int. Cl. H01L 33/00; H01L 27/15; H01L 21/68; H01L 21/67

(52) U.S. Cl. CPC H01L 33/005; H01L 21/67132; H01L 21/68; H01L 27/156

(57) ABSTRACT

The present disclosure provides a mass transfer system for a semiconductor element. The mass transfer system is configured to transfer the semiconductor element arranged on a temporary substrate to a target substrate. The transfer system includes an accelerating device and a rotating device. The accelerating device is configured to be applied with an accelerating electric field in a first direction, and provided with a first inlet and a first outlet which are disposed in the first direction and communicated with the accelerating electric field. The rotating device is configured to be applied with a magnetic field in a second direction, and provided with a second inlet and a second outlet which are communicated with the magnetic field. The second inlet is aligned with the first outlet. In addition, the disclosure also provides a mass transfer method for a semiconductor element.

### CROSS-REFERENCE TO RELATED APPLICATIONS

This application is a continuation of International Application No. PCT/CN2019/122816, filed on Dec. 3, 2019, the entire disclosures of which are incorporated herein by reference.

### TECHNICAL FIELD

The disclosure relates to a semiconductor element transfer technology, in particular to a mass transfer method and a mass transfer system for a semiconductor element.

### BACKGROUND

A micro light emitting diode (Micro-LED) as well as light emitting diode scaling and matrixing technologies presents advantages in stability, service life and operating temperature. The micro-LED also inherits advantages of low power consumption, high color saturation, fast response, strong contrast and the like of a light emitting diode. Meanwhile, the micro-LED provides higher brightness and lower power consumption, among others.

Therefore, the micro-LED has great application prospect in the future, such as in a micro-LED display screen. However, there are some difficulties to manufacture the micro-LED display screen, because a backplate of the micro-LED display screen contains tens of thousands of light emitting diodes which need to be transferred at one time in manufacturing the micro-LED display screen. Therefore, how to simultaneously fulfill both efficiency and yield is an urgent problem to be solved in mass production of the micro-LED display screen.

At present, existing major mass transfer methods include picking/transferring, fluid transfer and others. However, in current mass transfer technologies, transfer time is longer due to the limited number of light-emitting diodes picked up at one time in picking/transferring. Meanwhile, absence and redundancy are easy to occur in fluid transfer, and accuracy of positions for light-emitting diodes to be placed at needs to be improved.

### SUMMARY

The disclosure provides a mass transfer method and a mass transfer system for a semiconductor element in a principle that a motion trajectory of an electric charge is changed by a magnetic field.

In a first aspect, implementations of the present disclosure provide a mass transfer system for a semiconductor element. The mass transfer system is configured to transfer the semiconductor element arranged on a temporary substrate to a target substrate. The semiconductor element carries electric charges. The transfer system includes an accelerating device and a rotating device.

The accelerating device is configured to be applied with an accelerating electric field in a first direction and provided with a first inlet and a first outlet which are disposed in the first direction and communicated with the accelerating electric field. The first inlet is aligned with a target semiconductor element which needs to be transferred to the target substrate, and the target semiconductor element is configured to be detached from the temporary substrate to pass through the first outlet, under action of the accelerating electric field.

The rotating device is configured to be applied with a magnetic field in a second direction and provided with a second inlet and a second outlet which are communicated with the magnetic field. The second inlet is aligned with the first outlet and is configured for the target semiconductor element, which passes out of the accelerating electric field through the first outlet, to enter the magnetic field. The target semiconductor element is configured to pass through the second outlet along a corresponding motion trajectory under action of the magnetic field, and the motion trajectory is perpendicular to the second direction. The second outlet corresponds to a position on the target substrate that the target semiconductor element is to be transferred to.

In a second aspect, implementations of the present disclosure provide a mass transfer method for a semiconductor element for transferring the semiconductor element arranged on a temporary substrate to a target substrate. The mass transfer method includes following operations.

An accelerating device is provided. The accelerating device is configured to be applied with an accelerating electric field in a first direction, and provided with a first inlet and a first outlet which are disposed in the first direction and communicated with the accelerating electric field.

A rotating device is provided. The rotating device is configured to be applied with a magnetic field in a second direction, and provided with a second inlet and a second outlet which are communicated with the magnetic field. The second inlet is aligned with the first outlet.

The temporary substrate is placed at the first inlet and the first inlet is aligned with a target semiconductor element to be transferred to the target substrate.

The target semiconductor element is detached from the temporary substrate and the target semiconductor element is made to pass through the first outlet, under action of the accelerating electric field.

The target semiconductor element is made to pass through the second outlet along a corresponding motion trajectory, under action of the magnetic field, after the target semiconductor element passes out of the accelerating electric field through the first outlet and enters the magnetic field from the second inlet.

The target semiconductor element is placed on which a position that the target semiconductor element is to be transferred to corresponds to the second outlet, to make the target semiconductor element pass out of the magnetic field through the second outlet to be placed at the position.

According to the mass transfer method and the mass transfer system for a semiconductor element described above, the semiconductor element is transferred from the temporary substrate to the target substrate by making the semiconductor element carry electric charges and perform a uniform circular motion in the magnetic field. In a transfer process, both transfer speed and accuracy of placing the semiconductor element at a corresponding position on the target substrate are effectively contemplated.

### BRIEF DESCRIPTION OF THE DRAWINGS

FIG. 1 is a schematic diagram of a mass transfer system according to implementations of the present disclosure.

FIG. 2 is a schematic diagram of a mass transfer system according to other implementations of the present disclosure.

FIG. 3 is a schematic diagram of a mass transfer system according to other implementations of the present disclosure.

FIG. 4 is a schematic diagram of a mass transfer system according to other implementations of the present disclosure.

FIG. 5 is a schematic diagram of a mass transfer system according to other implementations of the present disclosure.

FIG. 6 is a schematic flow chart of a mass transfer method according to implementations of the present disclosure.

FIG. 7 is a schematic diagram of the mass transfer system according to other implementations of the present disclosure.

FIG. 8 is a schematic diagram of the mass transfer system according to other implementations of the present disclosure.

FIG. 9 is a schematic diagram of the mass transfer system according to other implementations of the present disclosure.

FIG. 10 is a schematic diagram of the mass transfer system according to other implementations of the present disclosure.

FIG. 11 is a schematic sub-flow chart of a mass transfer method according to other implementations of the present disclosure.

### DETAILED DESCRIPTION

In order to understand content of the present disclosure more clearly and precisely, detailed description will now be made with reference to attached drawings. The accompanying drawings illustrate examples of implementations of the present disclosure, in which like reference numerals refer to like elements throughout. It should be understood that the drawings are not to scale as an actual implementation of the disclosure, but are for illustrative purposes, and not drawn according to original dimensions.

FIG. 1 is a schematic diagram of a mass transfer system 1000 according to implementations of the present disclosure. Now reference is made to FIG. 1, the mass transfer system 1000 is configured to transfer a semiconductor element(s) 20 placed on a temporary substrate 10 to a target substrate 30 one by one, and place the semiconductor element 20 at a position on the target substrate 30 that the target semiconductor element is to be transferred to. Specifically, the semiconductor element 20 may be a micro light emitting diode. The semiconductor elements 20 are arranged in a matrix at intervals on the temporary substrate 10. The target substrate 30 may be a backplate of a display device. The display device can be a display, television, and other electronic products with a displaying function.

Specifically, the mass transfer system 1000 includes an accelerating device 40 and a rotating device 50. Specifically, the accelerating device 40 is configured to be applied with an acceleration electric field E in a first direction, and provided with a first inlet 41 and a first outlet 42 which are disposed in the first direction and communicated with the acceleration electric field E. The rotating device 50 is configured to be applied with a magnetic field B in a second direction, and provided with a second inlet 51 and a second outlet 52 communicated with the magnetic field B. The second inlet 51 is aligned with the first outlet 42 and is configured for a target semiconductor element 21, which passes out of the accelerating electric field E through the first outlet 42, to enter the magnetic field B.

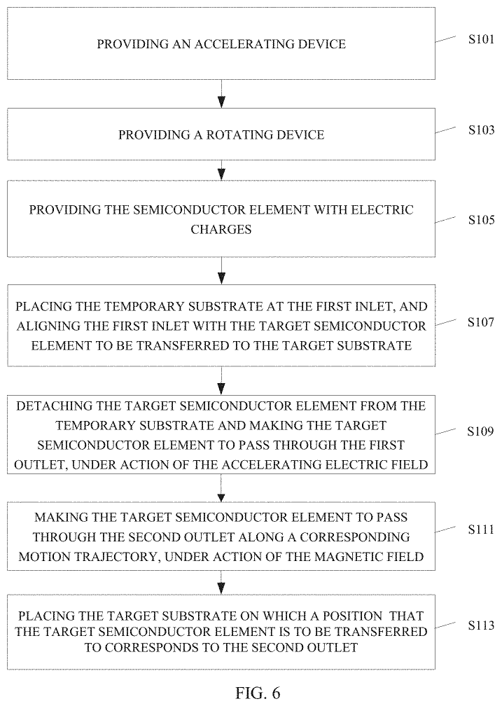

FIG. 6 is a schematic flow chart of a mass transfer method according to implementations of the present disclosure. Reference is made to FIG. 6, the mass transfer system 1000 is operated in transferring the semiconductor element 20 to the target substrate 30 as follows.

At S101, an accelerating device 40 is provided.

At S103, a rotating device 50 is provided.

At Step S105, the semiconductor element 20 is provided with electric charges. The electric charges can be either positive or negative.

At Step S107, the temporary substrate 10 is placed at the first inlet 41, and the first inlet 41 is aligned with the target semiconductor element 21 to be transferred to the target substrate 30. Specifically, the first inlet 41 is aligned with a target semiconductor element 21 on the temporary substrate 10.

At Step S109, the target semiconductor element 21 is detached from the temporary substrate 10 and the target semiconductor element 21 is made to pass out of the first outlet 42, under action of the accelerating electric field E. A relationship between a moving direction of the target semiconductor element 21 and the first direction is determined according to the charge in the target semiconductor element 21, which will be described in detail below.

At Step S111, the target semiconductor element 21 is made to pass through the second outlet 52 along a corresponding motion trajectory, under action of the magnetic field B. Specifically, The target semiconductor element 21 is made to pass through the second outlet 52 along the corresponding motion trajectory, under action of the magnetic field B, after the target semiconductor element 21 passes out of the accelerating electric field E through the first outlet 42 and enters the magnetic field B from the second inlet 51. The motion trajectory of the target semiconductor element 21 is perpendicular to the second direction.

At Step S113, the target substrate 30 is placed on which a position that the target semiconductor element 21 is to be transferred to corresponds to the second outlet 52. Specifically, the target substrate 30 is placed at the second outlet 52, so that the target semiconductor element 21 passes out of the magnetic field B through the second outlet 52 and is placed at the position on the target substrate 30 that the target semiconductor element 21 is to be transferred to.

In other words, the position on the target substrate that the target semiconductor element is to be transferred is placed to correspond to the second outlet, to make the target semiconductor element pass out of the decelerating electric field through the second outlet to be placed at the position.

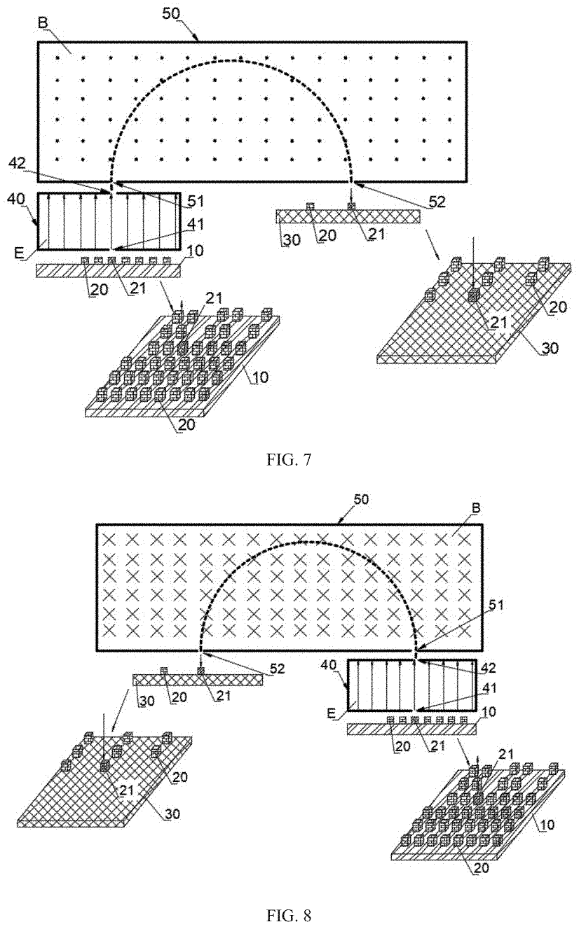

Now reference is made to FIG. 7, which is a schematic diagram of a mass transfer system 1100 according to implementations of the present disclosure. Specifically, the semiconductor element 20 is positively charged, and an acceleration direction of the target semiconductor element 21 in the acceleration electric field E is the same as the first direction. The second direction is perpendicular to a paper plane and out of the paper, and the target semiconductor element 21 performs a uniform circular motion in a clockwise direction in the magnetic field B, and passes out of the magnetic field B through the second outlet 52 after rotating by 180 degrees.

FIG. 8 is a schematic diagram of a mass transfer system 1200 according to implementations of the present disclosure. Reference is made to FIG. 8, the semiconductor element 20 is positively charged, and an acceleration direction of the target semiconductor element 21 in the acceleration electric field E is the same as the first direction. The second direction is perpendicular to a paper plane and into the paper, and the target semiconductor element 21 performs a uniform circular motion in a counterclockwise direction in the magnetic field B, and passes out of the magnetic field B through the second outlet 52 after rotating by 180 degrees.

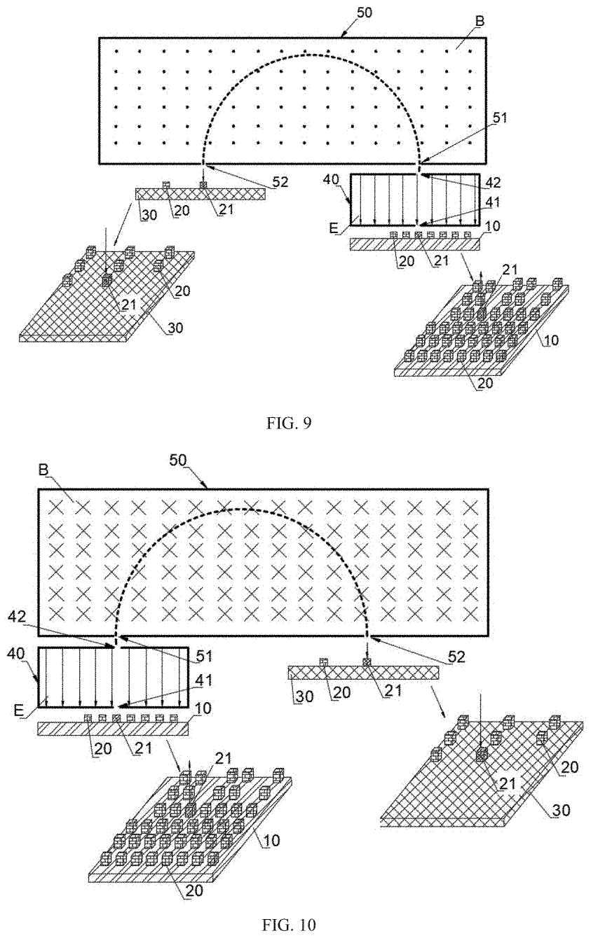

FIG. 9 is a schematic diagram of a mass transfer system 1300 according to implementations of the present disclosure. Reference is made to FIG. 9, the semiconductor element 20 is negatively charged, and the acceleration direction of the target semiconductor element 21 in the acceleration electric field E is opposite to the first direction. The second direction is perpendicular to a paper plane and out of the paper, and the target semiconductor element 21 performs a uniform circular motion in a counterclockwise direction in the magnetic field B, and passes out of the magnetic field B through the second outlet 52 after rotating by 180 degrees.

FIG. 10 is a schematic diagram of a mass transfer system 1400 according to implementations of the present disclosure. Reference is made to FIG. 10, the semiconductor element 20 is negatively charged, and the acceleration direction of the target semiconductor element 21 in the acceleration electric field E is opposite to the first direction. The second direction is perpendicular to a paper plane and into the paper, and the target semiconductor element 21 performs a uniform circular motion in the clockwise direction in the magnetic field B, and passes out of the magnetic field B through the second outlet 52 after rotating by 180 degrees.

In the above implementations, the accelerating electric field E is an electric field in a plate capacitor, and the magnetic field B is a uniform magnetic field. Since the semiconductor element 20 has characteristics of small size and light weight, when the target semiconductor element 21 moves in the accelerating electric field E and the magnetic field B, the target semiconductor element 21 can be regarded as a particle and its gravity can be ignored. By constantly moving the temporary substrate 10 and the target substrate 30, it is possible to transfer the semiconductor elements 20 from the temporary substrate 10 to the target substrate 30 one by one.

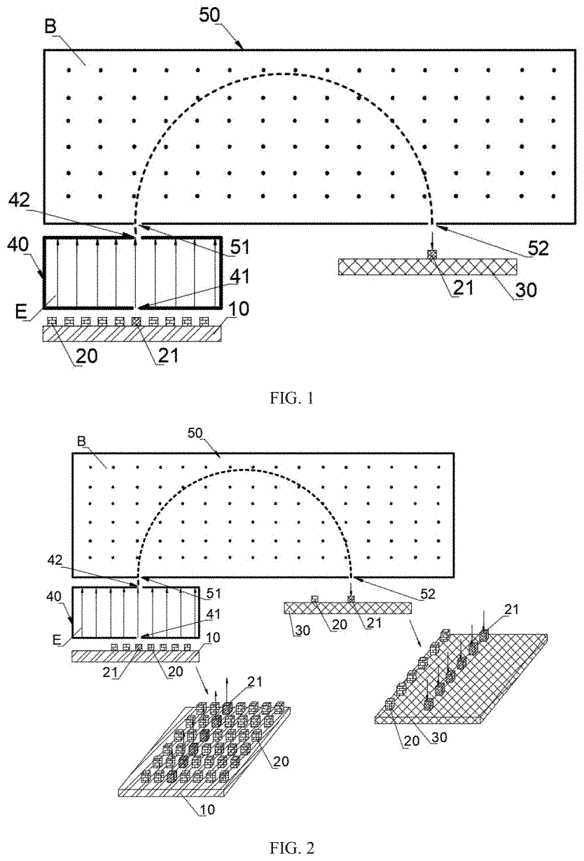

FIG. 2 is a schematic diagram of a mass transfer system 2000 according to other implementations of the present disclosure. As illustrated in FIG. 2, the mass transfer system 2000 is different from the mass transfer system 1000 in that the mass transfer system 2000 can transfer the semiconductor elements 20 placed on the temporary substrate 10 to the target substrate 30 row by row or column by column, and place the semiconductor elements 20 at positions on the target substrate 30 that the target semiconductor elements are to be transferred to. Specifically, the first inlet 41 and the first outlet 42 respectively are a plurality of openings which are disposed on opposite ends (e.g., surfaces) of the accelerating device 40 at intervals and are in one-to-one correspondence with a row or a column of the target semiconductor elements 21, and the first inlet 41 and the first outlet 42 are each arranged on the accelerating device 40 in a straight strip form. The second inlet 51 and the second outlet 52 respectively are a plurality of openings disposed arranged on a same end (e.g., surface) of the rotating device 50, and the second inlet 51 and the second outlet 52 are each arranged on the rotating device 50 in a straight strip form. Other processes of transferring the target semiconductor element 21 to the target substrate 30 by the mass transfer system 2000 are basically the same as those of the mass transfer system 1000, which will not be described repeatedly here again.

In the above implementations, by constantly moving the temporary substrate 10 and the target substrate 30, it is possible to transfer the semiconductor elements 20 from the temporary substrate 10 to the target substrate 30 row by row or column by column.

FIG. 3 is a schematic diagram of a mass transfer system 3000 according to other implementations of the present disclosure. As illustrated in FIG. 3, the mass transfer system 3000 is different from the mass transfer system 2000 in that the mass transfer system 3000 can transfer the semiconductor elements 20 placed on the temporary substrate 10 to the target substrate 30 in multiple rows or columns, and place the semiconductor elements 20 at positions on the target substrate 30 that the target semiconductor elements are to be transferred to. Specifically, the first inlet 41 and the first outlet 42 respectively are a plurality of openings which are disposed on opposite ends of the accelerating device 40 at intervals and are in one-to-one correspondence with the target semiconductor elements 21 arranged in a matrix, and the first inlet 41 and the first outlet 42 are each arranged on the accelerating device 40 in a matrix. The second inlet 51 and the second outlet 52 respectively are a plurality of openings disposed arranged on a same end of the rotating device 50, and the second inlet 51 and the second outlet 52 are each arranged on the rotating device 50 in a matrix. Other processes of transferring the target semiconductor element 21 to the target substrate 30 by the mass transfer system 3000 are basically the same as those of the mass transfer system 2000, which will not be described repeatedly here again.

In the above implementations, by constantly moving the temporary substrate 10 and the target substrate 30, it is possible to transfer the semiconductor elements 20 from the temporary substrate 10 to the target substrate 30 in multiple rows or columns.

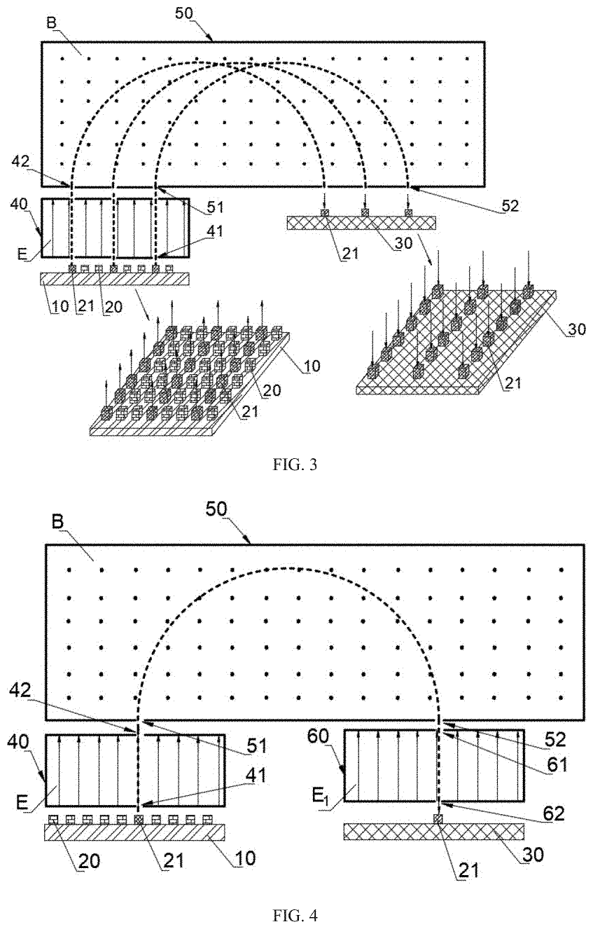

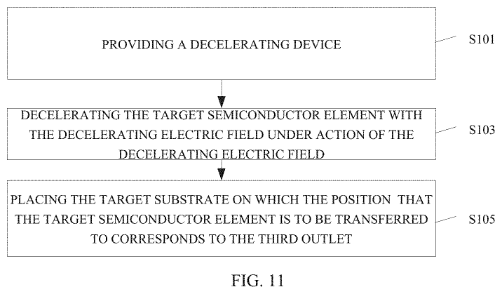

FIG. 4 is a schematic diagram of a mass transfer system 4000 according to other implementations of the present disclosure. As illustrated in FIG. 4, the mass transfer system 4000 is different from the mass transfer system 3000 in that the mass transfer system 4000 further includes a decelerating device 60 disposed between the rotating device 50 and the target substrate 30. As illustrated in FIG. 11, transferring the target semiconductor element 21 to the target substrate 30 by the mass transfer system 4000 further includes following operations.

At Step S1081, a decelerating device 60 is provided. The decelerating device 60 is configured to be applied with a decelerating electric field E₁ in a third direction, and provided with a third inlet 61 and a third outlet 62 which are disposed in the third direction and communicated with the decelerating electric field E₁. The third inlet 61 is aligned with the second outlet 52.

At Step S1082, the target semiconductor element 21 is decelerated with the decelerating electric field E₁ under action of the decelerating electric field E₁ to reduce a moving speed of the target semiconductor element to a safe speed threshold and the target semiconductor element 21 is made to pass through the third outlet 62, after the target semiconductor element 21 passes out of the magnetic field B through the second outlet 52 and enters the decelerating electric field E₁ from the third inlet 61. The target semiconductor element 21 moves in a direction same as or opposite to the third direction under action of the decelerating electric field E₁. Specifically, a relationship between a moving direction of the target semiconductor element 21 and the first direction is determined according to the charge in the target semiconductor element 21. When the target semiconductor element 21 is positively charged, the moving direction of the target semiconductor element 21 in the decelerating electric field E₁ is opposite to the third direction. When the target semiconductor element 21 is negatively charged, the moving direction of the target semiconductor element 21 in the decelerating electric field E₁ is the same as the third direction.

At Step S1083, the target substrate 30 is placed on which the position that the target semiconductor element 21 is to be transferred to corresponds to the third outlet 62. Specifically, the target substrate 30 is placed at the third outlet 62, so that the target semiconductor element 21 passes out of the decelerating electric field E₁ through the third outlet 62 and is placed at the position on the target substrate 30 that the target semiconductor element 21 is to be transferred to.

In other words, the position on the target substrate that the target semiconductor element is to be transferred is placed to correspond to the second outlet, to make the target semiconductor element pass out of the decelerating electric field through the third outlet to be placed at the position.

Other processes of transferring the target semiconductor element 21 to the target substrate 30 by the mass transfer system 4000 are basically the same as those of the mass transfer system 3000, which will not be described repeatedly here again.

In the above implementations, the decelerating electric field E₁ in the decelerating device 60 is the electric field in the plate capacitor. After the target semiconductor element 21 leaves the magnetic field B, the target semiconductor element 21 is decelerated by the decelerating electric field E₁, so that the target semiconductor element 21 will not damage the target substrate 30 due to excessive speed when placed on the target substrate 30.

In some implementations, when the semiconductor elements 20 placed on the temporary substrate 10 are transferred to the target substrate 30 row by row or column by column and the semiconductor elements 20 are placed at the positions on the target substrate 30 that the target semiconductor elements are to be transferred to, the third inlet 61 and the third outlet 62 respectively are a plurality of openings which are disposed on opposite ends of the decelerating device 60 at intervals and are in one-to-one correspondence with a row or a column of the target semiconductor elements 21, and the third inlet 61 and the third outlet 62 are each arranged on the accelerating device 60 in a straight strip form.

In some implementations, when the semiconductor elements 20 placed on the temporary substrate 10 are transferred to the target substrate 30 in multiple rows or columns and the semiconductor elements 20 are placed at the positions on the target substrate 30 that the target semiconductor elements are to be transferred to, the third inlet 61 and the third outlet 62 respectively are a plurality of openings which are disposed on opposite ends of the decelerating device 60 at intervals and are in one-to-one correspondence with the target semiconductor elements 21 arranged in a matrix, and the third inlet 61 and the third outlet 62 are each arranged on the accelerating device 60 in a matrix.

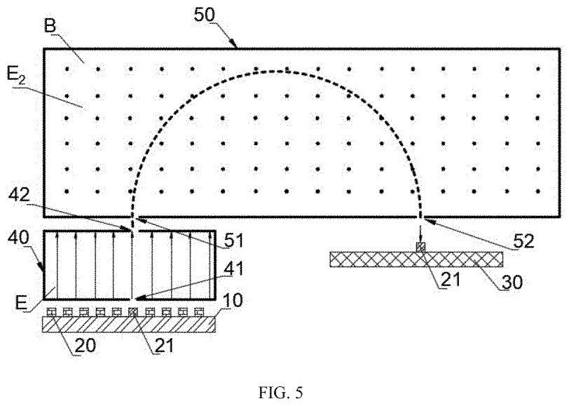

FIG. 5 is a schematic diagram of a mass transfer system 5000 according to other implementations of the present disclosure. Now reference is made to FIG. 5, the mass transfer system 5000 is different from the mass transfer system 4000 in that the rotating device 60 of the mass transfer system 5000 is further configured to be applied with an anti-gravity electric field E₂. Specifically, when a mass of the semiconductor element 20 cannot be ignored, that is, the semiconductor element 20 cannot be regarded as a particle, the rotating device 60 is configured to be applied with the anti-gravity electric field E₂. A fourth direction, which is a direction of the anti-gravity electric field E₂, is the same as or opposite to a gravity direction, so that the anti-gravity electric field force applied to the target semiconductor element 21 in the rotating device 60 is equal to the gravity of the target semiconductor element 21. The motion trajectory direction of the target semiconductor element 21 in the magnetic field B is perpendicular to the gravity direction, that is, the second direction is along the gravity direction. A relationship between the direction of the anti-gravity electric field E₂ and the gravity direction is determined according to the charge in the target semiconductor element 21. When the target semiconductor element 21 is positively charged, the direction of the anti-gravity electric field E₂ is opposite to the gravity direction. When the target semiconductor element 21 is negatively charged, the direction of the anti-gravity electric field E₂ is the same as the gravity direction. Other processes of transferring the target semiconductor element 21 to the target substrate 30 by the mass transfer system 5000 are basically the same as those of the mass transfer system 4000, which will not be described repeatedly here again.

In the above implementation, the anti-gravity electric field E₂ in the rotating device 60 is an electric field in the plate capacitor. Applying the anti-gravity electric field E₂ in the rotating device 60 can eliminate an influence of the gravity of the semiconductor element 20 in a mass transfer process.

In the above implementation, the magnetic field B is applied in the rotating device 50 to make the target semiconductor element 21 perform a uniform circular motion in the rotating device 50, so that both the transfer speed and the accuracy of placing the semiconductor element are contemplated in transferring the semiconductor element 20 to the target substrate 30.

Obviously, various modifications and variations can be made by those skilled in the art without departing from the spirit and scope of the disclosure. In this way, in a case where these modifications and variations of the present disclosure fall within the scope of the claims and their equivalents, the present disclosure is also intended to encompass these modifications and variations.

The above examples are only the preferred implementations of the present disclosure, which of course cannot be constructed to limit the scope of the present disclosure. Therefore the equivalent changes made in view of the claims of the present disclosure still belong to the scope covered by the present disclosure.

What is claimed is:

1. A mass transfer system for a semiconductor element, the mass transfer system being configured to transfer the semiconductor element arranged on a temporary substrate to a target substrate, wherein the semiconductor element carries electric charges, and the transfer system comprises:
an accelerating device configured to be applied with an accelerating electric field in a first direction and provided with a first inlet and a first outlet which are disposed in the first direction and communicated with the accelerating electric field, wherein the first inlet is aligned with a target semiconductor element which needs to be transferred to the target substrate, and the target semiconductor element is configured to be detached from the temporary substrate to pass through the first outlet, under action of the accelerating electric field;
a rotating device configured to be applied with a magnetic field in a second direction and provided with a second inlet and a second outlet which are communicated with the magnetic field, wherein the second inlet is aligned with the first outlet and is configured for the target semiconductor element, which passes through the accelerating electric field from the first outlet, to enter the magnetic field; wherein the target semiconductor element is configured to pass through the second outlet along a corresponding motion trajectory under action of the magnetic field, the motion trajectory is perpendicular to the second direction, and the second outlet corresponds to a position on the target substrate that the target semiconductor element is to be transferred to.

2. The mass transfer system of claim 1, further comprising:
a decelerating device configured to be applied with a decelerating electric field in a third direction, and provided with a third inlet and a third outlet which are disposed in the third direction and communicated with the decelerating electric field, wherein the third inlet is aligned with the second outlet and is configured for the target semiconductor element, which passes out of the magnetic field through the second outlet, to enter the decelerating electric field; wherein the decelerating device is configured to decelerate the target semiconductor element to reduce a moving speed of the target semiconductor element to a safe speed threshold; the target semiconductor element is configured to pass through the third outlet under action of the decelerating electric field, and the third outlet corresponds to a position on the target substrate that the target semiconductor element is to be transferred to.

3. The mass transfer system of claim 2, wherein the target semiconductor element is implemented as a plurality of target semiconductor elements; wherein the first inlet and the first outlet respectively are a plurality of openings, wherein the plurality of openings are disposed on opposite ends of the accelerating device at intervals, and are in one-to-one correspondence with target semiconductor elements; and wherein the second inlet and the second outlet respectively are a plurality of openings disposed on a same end of the rotating device.

4. The mass transfer system of claim 3, wherein the first inlet and the first outlet are each arranged on the accelerating device in a straight strip form, and the second inlet and the second outlet are each arranged on the rotating device in a straight strip form.

5. The mass transfer system of claim 3, wherein the first inlet and the first outlet are each arranged on the accelerating device in a matrix, and the second inlet and the second outlet are each arranged on the rotating device in a matrix.

6. The mass transfer system of claim 2, wherein the target semiconductor element is implemented as a plurality of target semiconductor elements; wherein the third inlet and the third outlet respectively are a plurality of openings, wherein the plurality of openings are disposed on opposite ends of the decelerating device at intervals, and are in one-to-one correspondence with target semiconductor elements.

7. The mass transfer system of claim 6, wherein the third inlet and the third outlet are each arranged on the decelerating device in a straight strip form.

8. The mass transfer system of claim 6, wherein third inlet and the third outlet are each arranged in a matrix on the decelerating device in a matrix.

9. The mass transfer system of claim 1, wherein the rotating device is further configured to be applied with an anti-gravity electric field, so that the target semiconductor element is subjected to an anti-gravity electric field force equal to its gravity in the rotating device.

10. A mass transfer method for a semiconductor element for transferring the semiconductor element arranged on a temporary substrate to a target substrate, wherein the mass transfer method comprises:
providing an accelerating device, the accelerating device being configured to be applied with an accelerating electric field in a first direction, and provided with a first inlet and a first outlet which are disposed in the first direction and communicated with the accelerating electric field;
providing a rotating device, the rotating device being configured to be applied with a magnetic field in a second direction, and a second inlet and a second outlet which are communicated with the magnetic field, wherein the second inlet is aligned with the first outlet;
placing the temporary substrate at the first inlet and aligning the first inlet with a target semiconductor element to be transferred to the target substrate;
detaching the target semiconductor element from the temporary substrate and making the target semiconductor element pass through the first outlet, under action of the accelerating electric field;
making the target semiconductor element pass through the second outlet along a corresponding motion trajectory, under action of the magnetic field, after the target semiconductor element passing out of the accelerating electric field through the first outlet and entering the magnetic field from the second inlet; and
placing the target substrate on which a position that the target semiconductor element is to be transferred to corresponds to the second outlet, to make the target semiconductor element pass out of the magnetic field through the second outlet to be placed at the position.

11. The mass transfer method of claim 10, further comprising:
after the target semiconductor element passes out of the magnetic field through the second outlet and before the target semiconductor element is placed at the position where the target semiconductor element is to be transferred,
providing a decelerating device, the decelerating device being configured to be applied with a decelerating electric field in a third direction, and provided with a third inlet and a third outlet which are disposed in the third direction and communicated with the decelerating electric field, wherein the third inlet is aligned with the second outlet;
decelerating, with the decelerating electric field, the target semiconductor element under action of the decelerating electric field to reduce a moving speed of the target semiconductor element to a safe speed threshold and make the target semiconductor element pass through the third outlet, after the target semiconductor element passes out of the magnetic field through the second outlet and enters the decelerating electric field from the third inlet; and
placing the target substrate on which the position that the target semiconductor element is to be transferred to corresponds to the second outlet, to make the target semiconductor element pass out of the decelerating electric field through the third outlet to be placed at the position.

12. The mass transfer method of claim 10, wherein the target semiconductor element is implemented as a plurality of target semiconductor elements; wherein the first inlet and the first outlet respectively are a plurality of openings, wherein the plurality of openings are disposed on opposite ends of the accelerating device at intervals, and are in one-to-one correspondence with target semiconductor elements; wherein the second inlet and the second outlet respectively are a plurality of openings disposed on a same end of the rotating device.

13. The mass transfer method of claim 12, wherein the first inlet and the first outlet are each arranged on the accelerating device in a straight strip form, and the second inlet and the second outlet are each arranged on the rotating device in a straight strip form.

14. The mass transfer method of claim 12, wherein the first inlet and the first outlet are each arranged on the accelerating device in a matrix, and the second inlet and the second outlet are each arranged on the rotating device in a matrix.

15. The mass transfer method of claim 11, wherein the target semiconductor element is implemented as a plurality of target semiconductor elements; wherein the third inlet and the third outlet respectively are a plurality of openings, wherein the plurality of openings are disposed on opposite ends of the decelerating device at intervals, and are in one-to-one correspondence with target semiconductor elements.

16. The mass transfer method of claim 15, wherein the third inlet and the third outlet are each arranged on the decelerating device in a straight strip form.

17. The mass transfer method of claim 15, wherein the third inlet and the third outlet are each arranged in a matrix on the decelerating device in a matrix.

18. The mass transfer method of claim 10, further comprising:
applying an anti-gravity electric field to the rotating device in such a manner that an anti-gravity electric field force that the target semiconductor element subjected to in the rotating device is equal to the gravity of the target semiconductor element; and
making the target semiconductor element subject to an anti-gravity electric field force which is equal to the gravity of the target semiconductor element by using the anti-gravity electric field, after the target semiconductor element passing out of the accelerating electric field through the first outlet and entering the rotating device from the second inlet.

19. The mass transfer method of claim 10, further comprising:
before placing the temporary substrate at the first inlet,
providing the semiconductor element with electric charges.

20. The mass transfer method of claim 10, wherein the semiconductor element comprises a micro light emitting diode.
